(19) United States
(12) Patent Application Publication
(10) Pub. No.: US 2026/0293734 A1
(43) Pub. Date: Sep. 24, 2026

(54) POLYSiC INTERPOSER WITH MANDREL DEFINED VIAS

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/227,541

(22) Filed: Jun. 4, 2025

Related U.S. Application Data
(60) Provisional application No. 63/776,053, filed on Mar. 22, 2025.

(51) Int. Cl. H10W 70/692; H10W 44/00; H10W 70/05; H10W 70/60; H10W 70/63; H10W 70/66; H10W 74/01; H10W 74/10; H10W 90/00

(52) U.S. Cl. CPC H10W 70/692; H10W 44/501; H10W 70/095; H10W 70/611; H10W 70/635; H10W 70/66; H10W 74/01; H10W 74/114; H10W 90/00

(57) ABSTRACT

A method comprises shaping a silicon wafer to have a silicon base a silicon mandrel, forming a ceramic interposer over the silicon mandrel, removing the silicon mandrel from the ceramic interposer to form a through opening, and inserting via material in the through opening to form a via in the ceramic interposer. A ceramic interposer has a via extending from the front side to the back side of the ceramic interposer. A semiconductor package has a ceramic interposer made of a SiC powder heated and pressed into an amorphous poly-SiC ceramic with a via extending from the front side to the back side of the interposer, and a semiconductor chip on the front side of the ceramic interposer and connected to the via.

### CROSS-REFERENCE TO RELATED APPLICATIONS

This application claims priority to U.S. Provisional Patent Application No. 63/776,053, filed Mar. 22, 2025, which is hereby incorporated by reference in its entirety for all purposes as if fully set forth herein.

### TECHNICAL FIELD

The present disclosure relates to interposers, in particular, amorphous polySiC ceramic interposers with vias therethrough.

### BACKGROUND

Phased array beamformers and high speed communication applications of the future drive development for substrates with low eddy currents like SiC interposers.

However, high speed data transmission can be limited by eddy current noise generated in silicon interposers. Use of SiC as an interposer but the material is expensive and it is expensive to form through-silicon vias (TSVs). SiC or AlN ceramic interposer are expensive and difficult to etch vias into. SiC interposers are expensive and etching thru vias in SiC is also expensive and time consuming. Ceramic interposers are also expensive to make and difficult to manufacture.

There is a need for ceramic interposers with low eddy currents that are less expensive to manufacture.

### SUMMARY

According to aspects, there is provided a method comprising: providing a silicon wafer having a front side and a back side; shaping the silicon wafer to have a silicon base at the back side and a silicon mandrel having a proximal end at the silicon base and a distal end at the front side; forming a ceramic interposer comprising the silicon wafer having the silicon mandrel; removing the silicon mandrel from the ceramic interposer to form a through opening in the back side of the ceramic interposer; and inserting via material in the through opening to form a via in the ceramic interposer.

Aspects as in the preceding paragraph provides a method, wherein shaping the silicon wafer comprises: applying a photoresist pattern to the front side of the silicon wafer; and etching the silicon wafer through the photoresist pattern to remove exposed portions of the silicon wafer and form the silicon mandrel.

Aspects as in one of the preceding two paragraphs provides a method, wherein forming a ceramic interposer comprises: covering the front side of the silicon wafer having the silicon mandrel with a SiC powder; and heating and pressing the SiC powder into an amorphous polySiC ceramic.

Aspects as in one of the preceding three paragraphs provides a method, wherein removing the silicon mandrel from the ceramic interposer comprises washing the back side of the ceramic interposer with a fluid to dissolve the silicon base and the silicon mandrel.

Aspects as in one of the preceding four paragraphs provides a method, wherein inserting via material comprises squeegeeing a conductive paste into the through opening.

Aspects as in one of the preceding five paragraphs provides a method, comprising heating the ceramic interposer to anneal the via material.

Aspects as in one of the preceding six paragraphs provides a method, comprising applying a spin on glass layer to the front side of the ceramic interposer.

Aspects as in one of the preceding seven paragraphs provides a method, comprising etching the back side of the ceramic interposer through the through opening to remove a portion of the spin on glass layer.

Aspects as in one of the preceding eight paragraphs provides a method, comprising: cutting a hole through the spin on glass layer, so that the hole coincides with the through opening; and heating the via material in the through opening to thermally expand the via material to flow into the hole through the spin on glass layer.

Aspects as in one of the preceding nine paragraphs provides a method, comprising applying a semiconductor chip to the front side of the ceramic interposer.

Aspects as in one of the preceding ten paragraphs provides a method, comprising encapsulating the front side of the ceramic interposer.

According to aspects, there is provided a device comprising: an interposer having a front side and a back side, wherein the interposer comprises a SiC powder heated and pressed into an amorphous poly-SiC ceramic; and a via extending from the front side to the back side of the interposer.

Aspects as in the preceding paragraph provide a device, wherein the via comprises titanium and nickel.

Aspects as in one of the preceding two paragraphs provides a device, wherein the via extends from 200 µm to 600 µm.

Aspects as in one of the preceding three paragraphs provides a device, comprising a spin on glass layer applied to the front side of the ceramic substrate, wherein the via extends through the spin on glass layer.

According to aspects, there is provided a system comprising: an interposer having a front side and a back side, wherein the interposer comprises a SiC powder heated and pressed into an amorphous poly-SiC ceramic; a via extending from the front side to the back side of the interposer; and a semiconductor chip on the front side of the ceramic interposer and connected to the via.

Aspects as in the preceding paragraph provides a system, wherein the via extends from 200 µm to 600 µm and comprises titanium and nickel.

Aspects as in one of the preceding two paragraphs provides a system, comprising a spin on glass layer applied to the front side of the ceramic substrate between the semiconductor chip and the interposer, wherein the via extends through the spin on glass layer, wherein the spin on glass layer comprises particles having a relatively higher heat transfer coefficient than a material of the spin on glass layer.

Aspects as in one of the preceding three paragraphs provides a system, comprising an integrated passive device applied to the semiconductor chip.

Aspects as in one of the preceding four paragraphs provides a system, comprising an encapsulant encapsulating the semiconductor chip.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1A shows a cross-sectional side view of a silicon wafer before vias are therein formed.

FIG. 1B shows a cross-sectional side view of the silicon wafer of FIG. 1A, wherein a photoresist pattern is applied to the silicon wafer.

FIG. 1C shows a cross-sectional side view of the silicon wafer of FIG. 1B, wherein the silicon wafer is etched to produce silicon mandrels.

FIG. 1D shows a cross-sectional side view of the silicon mandrels of FIG. 1C, wherein the photoresist pattern is removed from the silicon mandrels.

FIG. 1E shows a cross-sectional side view of the silicon mandrels of FIG. 1D, wherein the silicon mandrels are covered with a SiC powder and hot pressed to form an amorphous polySiC ceramic.

FIG. 2A shows a cross-sectional side view of a ceramic interposer made by the process illustrated by FIGS. 1A-1E, wherein a silicon wafer is photoresist patterned and the silicon wafer is etched to form mandrels.

FIG. 2B shows a cross-sectional side view of the ceramic interposer and chips shown in FIG. 2A, wherein integrated passive devices (IPDs) may then be applied to the known good die (KGD) chips.

FIG. 2C shows a cross-sectional side view of the ceramic interposer and chips shown in FIG. 2B, wherein integrated passive devices (IPDs) on the front side of the chips is encapsulated with an epoxy.

FIG. 2D shows a cross-sectional side view of the ceramic interposer and encapsulated chips shown in FIG. 2C, wherein the package is flipped up-side-down to expose the backside of the silicon mandrels in the ceramic interposer to further processing.

FIG. 2E shows a cross-sectional side view of the up-side-down ceramic interposer and encapsulated chips shown in FIG. 2D, wherein a first reactive-ion etch or plasma process is done in the through openings.

FIG. 2F shows a cross-sectional side view of the up-side-down ceramic interposer and encapsulated chips shown in FIG. 2E, wherein a second reactive-ion etch or plasma process is done in the through openings to remove portions of the diamondized spin on glass (SOG) layer at the bottoms of the respective through openings.

FIG. 2G shows a cross-sectional side view of the up-side-down ceramic interposer and encapsulated chips shown in FIG. 2F, wherein a conductive paste material is inserted into the through openings.

FIG. 2H shows a cross-sectional side view of the ceramic interposer and encapsulated chips as shown in FIG. 2G, wherein the package is flipped back over so that the front side is up and the backside is down.

FIG. 3A shows a cross-sectional side view of a ceramic interposer having silicon mandrels.

FIG. 3B shows a cross-sectional side view of the ceramic interposer having silicon mandrels as shown in FIG. 3A, wherein lasers are used to cut small diameter holes.

FIG. 3C shows a cross-sectional side view of the ceramic interposer as shown in FIG. 3B, wherein it is flipped up-side-down to expose the backside to further processing.

FIG. 3D shows a cross-sectional side view of the ceramic interposer as shown in FIG. 3C, wherein a conductive paste material is inserted into the through openings.

FIG. 3E shows a cross-sectional side view of the ceramic interposer as shown in FIG. 3D, wherein the ceramic interposer is flipped up-side-down to expose the front side to further processing.

FIG. 3F shows a cross-sectional side view of the ceramic interposer as shown in FIG. 3E, wherein the lasers locally heat the conductive paste material.

FIG. 3G shows a cross-sectional side view of the ceramic interposer as shown in FIG. 3F, wherein the conductive paste material has flowed up through the small diameter holes to form ball pads.

FIG. 4 shows a flow chart of a method creating a ceramic interposer with through-silicon vias (TSV).

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided a process of creating a ceramic interposer. Creating a ceramic interposer using a pressed ceramic verses starting with a single crystal substrate. A silicon wafer has applied thereto a diamondized (with heat transfer nano-particles) Spin on Glass layer for improved heat transfer. A silicon mandrel is provided and a process is used to press SiC power to form the location of the thru vias. Use of pressed poly-SiC (powder) to form interposer. The interposer is processed and then the mandrel is removed. The etch is then finished and the via is filled with a squeegeed metal paste. This process may provide a less expensive interposer substrate with thru vias that has good heat transfer and low eddy currents.

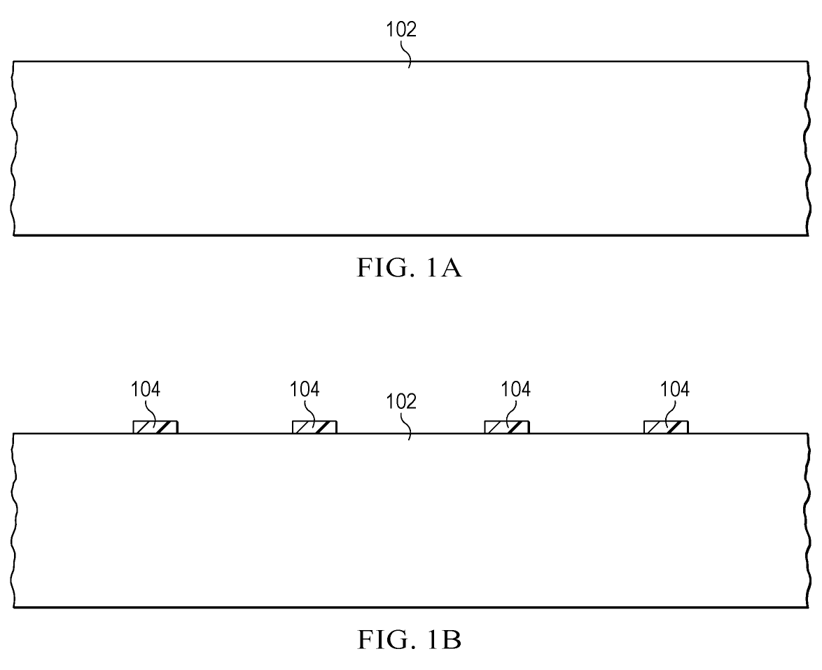

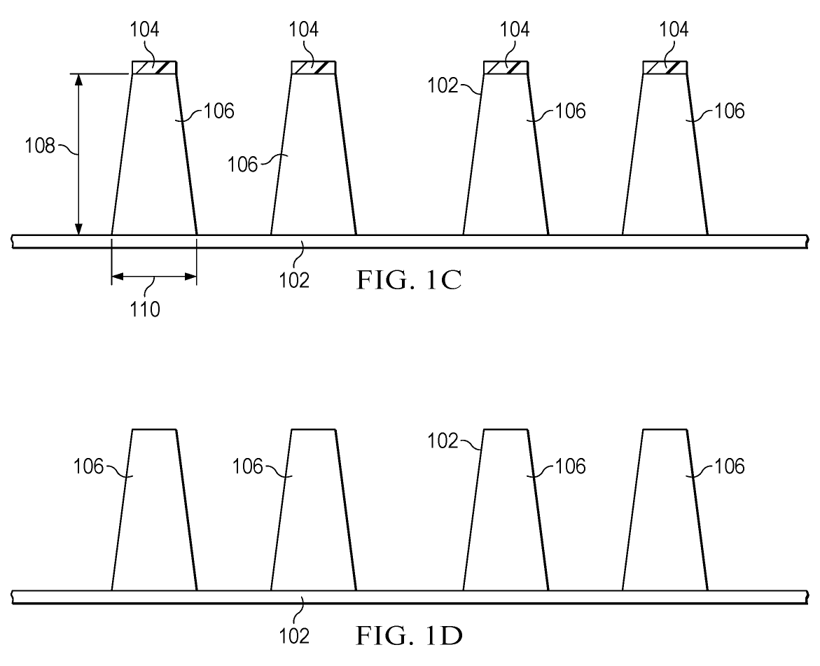

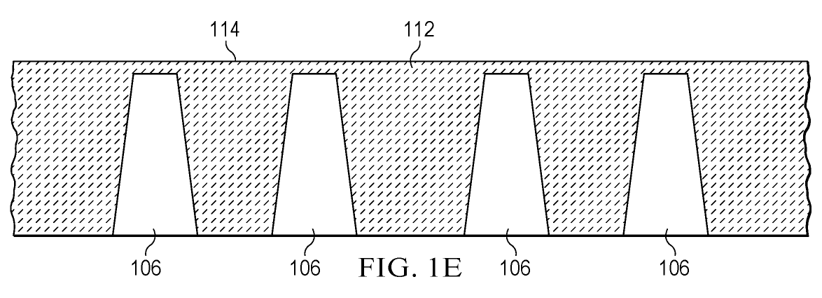

FIGS. 1A – 1E show fabrication of a pressed ceramic interposer having silicon mandrels.

FIG. 1A shows a cross-sectional side view of a silicon wafer 102 before vias are therein formed.

FIG. 1B shows a cross-sectional side view of the silicon wafer 102 of FIG. 1A. A photoresist pattern 104 is applied to the silicon wafer 102.

FIG. 1C shows a cross-sectional side view of the silicon wafer 102 of FIG. 1B. The silicon wafer 102 is etched to produce silicon mandrels 106. The silicon mandrels 106 may have a height 108 of 100-600 µm and a width 110 of 50-500 µm. The etch process may be a reactive-ion etch process. The silicon mandrels 106 may comprise tall silicon dots stacked to form a column or mandrel. Thin Si₃N₄ separation with may be obtained with polycrystalline silicon carbide (pSiC).

FIG. 1D shows a cross-sectional side view of the silicon mandrels 106 of FIG. 1C. The photoresist pattern 104 (see FIG. 1C) is removed from the silicon mandrels 106. A thin silicon nitride film (not shown) may then optionally be deposited.

FIG. 1E shows a cross-sectional side view of the silicon mandrels 106 of FIG. 1D. The silicon mandrels 106 are covered with a SiC powder and hot pressed to form an amorphous polySiC ceramic 112. Thus, a ceramic interposer 114 using a pressed ceramic is created.

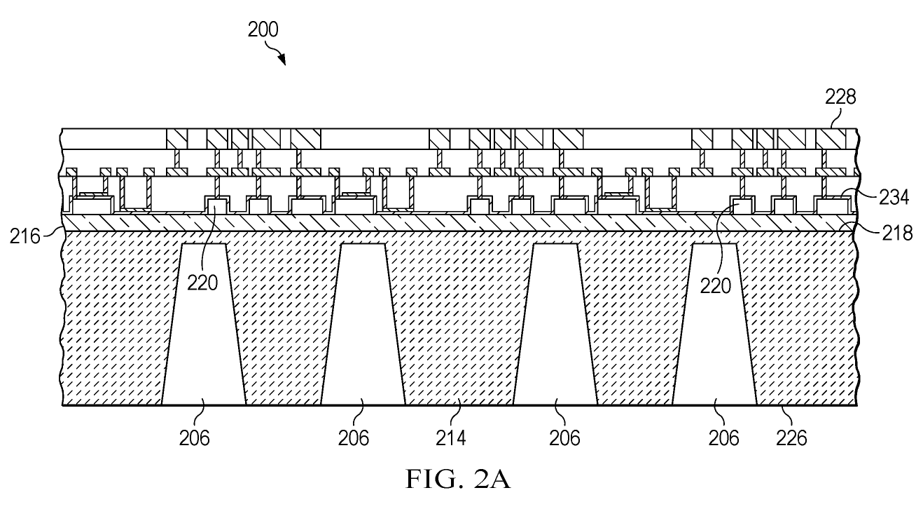

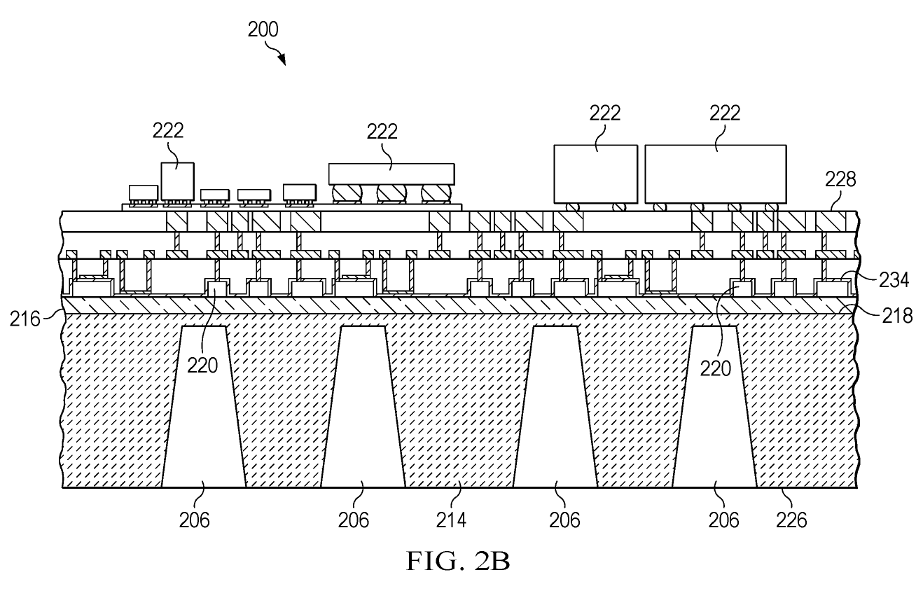

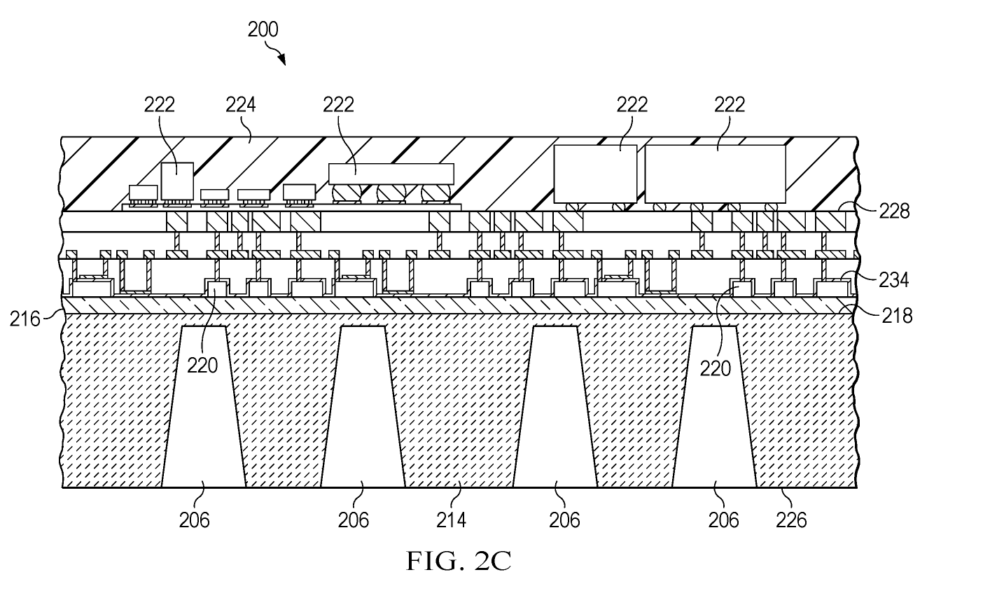

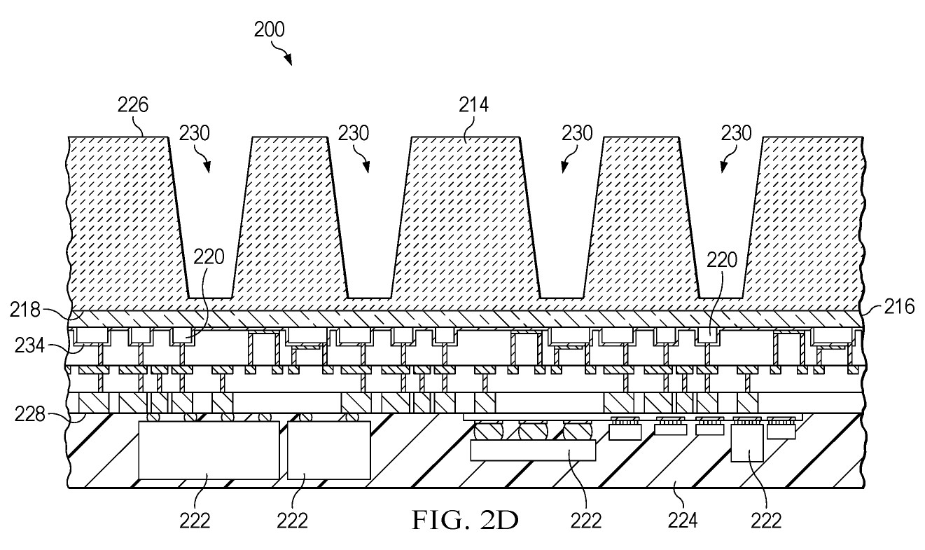

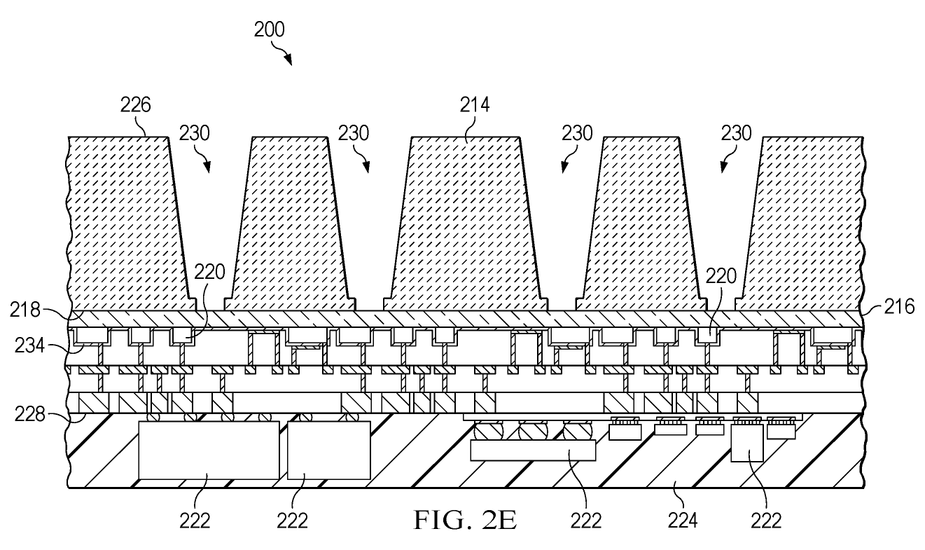

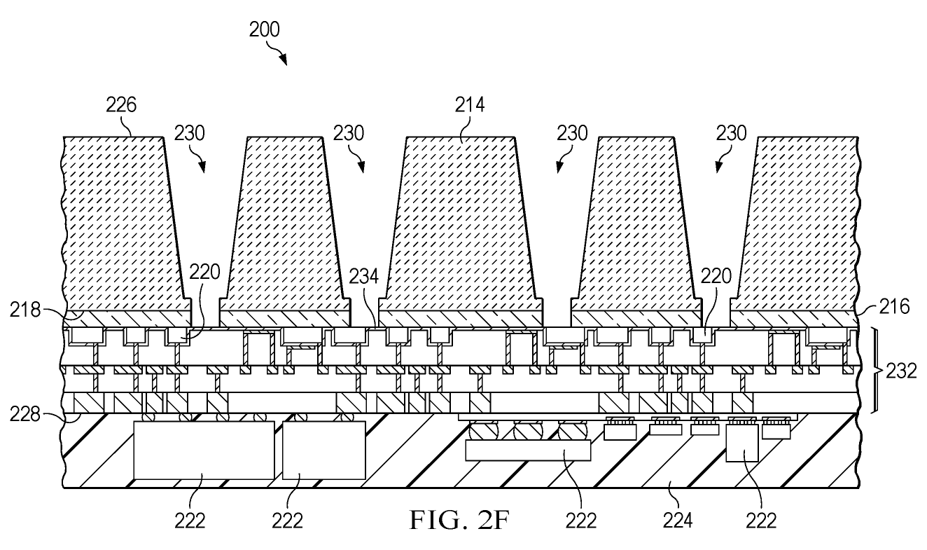

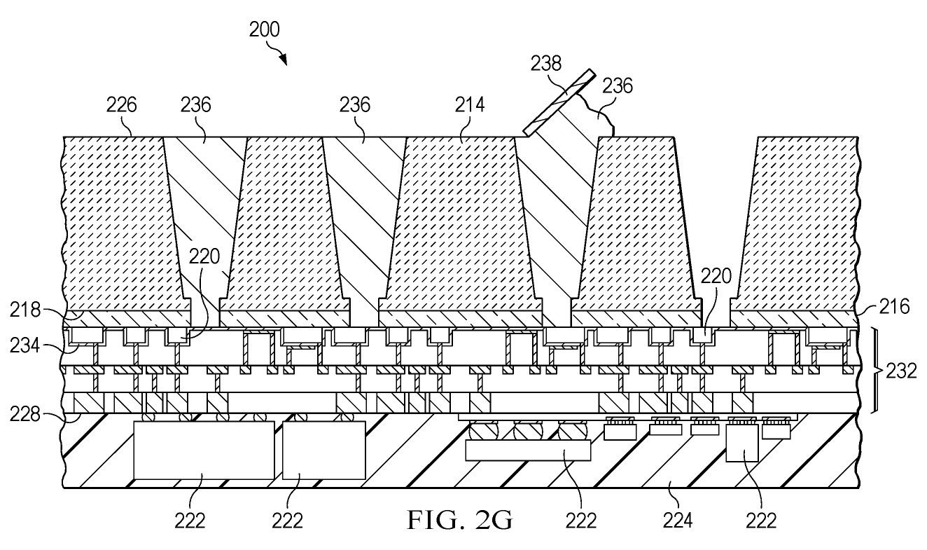

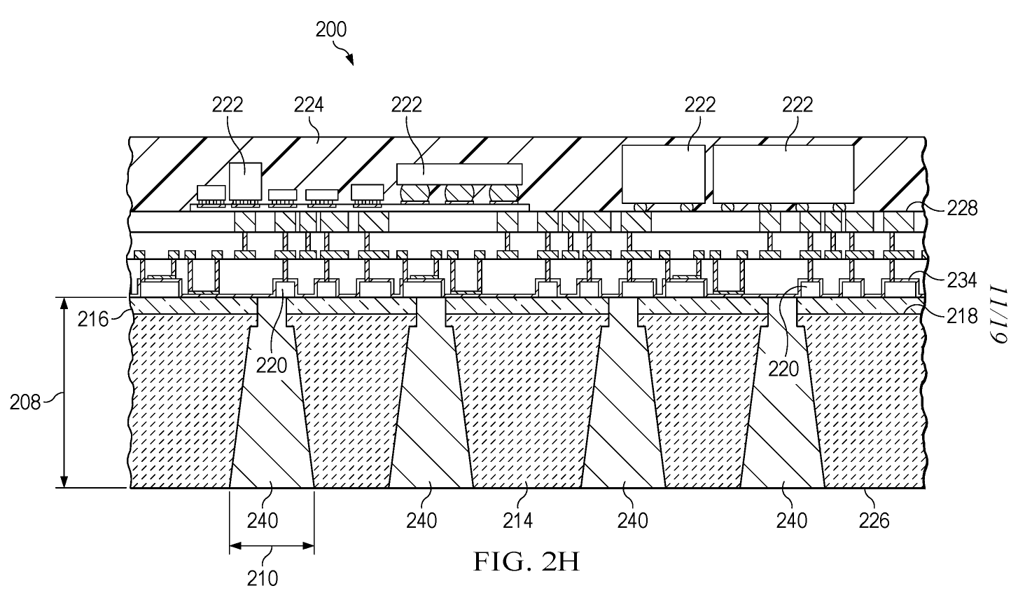

FIGS. 2A – 2H show fabrication of a ceramic interposer with through-silicon vias (TSV) and semiconductor package.

FIG. 2A shows a cross-sectional side view of a ceramic interposer 214 made by the process illustrated by FIGS. 1A-1E. A silicon wafer is photoresist patterned and the silicon wafer is etched to form mandrels. A diamondized spin on glass (SOG) layer 216 is applied to the front side 218 of the ceramic interposer 214 and annealed. The diamondized spin on glass (SOG) layer 216 may contain heat transfer enhancing particles, like diamond, AlN, or SiC, and may further provide a layer to reduce or prohibit eddy currents from being transferred through the package 200. Known good die (KGD) chips 220 may be applied to the diamondized spin on glass (SOG) layer 216 at strategically desired positions to align chip pads with the silicon mandrels 206 in the ceramic interposer 214.

FIG. 2B shows a cross-sectional side view of the ceramic interposer and chips shown in FIG. 2A. Integrated passive devices (IPDs) may then be applied to the known good die (KGD) chips. These may include high bandwidth memory (HBM) and system on chip (SOC) devices that may include: a central processing unit (CPU), memory, and I/O. The IPD (Integrated Passive Devices) may include: resistors, capacitors, and inductors.

FIG. 2C shows a cross-sectional side view of the ceramic interposer 214 and chips 220 shown in FIG. 2B. Integrated passive devices (IPDs) 222 on the front side 228 of the chips 220 may then be encapsulated with an epoxy 224 to protect these components during further processing.

FIG. 2D shows a cross-sectional side view of the ceramic interposer 214 and encapsulated chips 220 shown in FIG. 2C. However, the package 200 is flipped up-side-down to expose the backside 226 of the silicon mandrels 206 (see FIG. 2C) in the ceramic interposer 214 to further processing. The silicon mandrels 206 may be removed from the ceramic interposer 214 by a potassium hydroxide (KOH) wash, to produce through openings 230 in the ceramic interposer 214.

FIG. 2E shows a cross-sectional side view of the up-side-down ceramic interposer 214 and encapsulated chips 220 shown in FIG. 2D. A first reactive-ion etch or plasma process may then be done in the through openings 230, in the ceramic interposer 214, to remove the hot pressed amorphous polySiC ceramic material at the bottoms of the respective through openings 230 to expose the spin on glass (SOG) layer 216.

FIG. 2F shows a cross-sectional side view of the up-side-down ceramic interposer 214 and encapsulated chips 220 shown in FIG. 2E. A second reactive-ion etch or plasma process may then be done in the through openings 230, in the ceramic interposer 214, to remove portions of the diamondized spin on glass (SOG) layer 216 at the bottoms of the respective through openings 230, so that the first metal layer 234 of the metal stack 232 of the known good die (KGD) chips 220 is now exposed.

FIG. 2G shows a cross-sectional side view of the up-side-down ceramic interposer 214 and encapsulated chips 220 shown in FIG. 2F. A conductive paste material 236, for example Ti/Ni (Ag-Sn Ink Squeegee) material or copper-based material, is then inserted into the through openings 230 (see FIG. 2F) via a squeegee 238 or other process.

FIG. 2H shows a cross-sectional side view of the ceramic interposer 214 and encapsulated chips 220 shown in FIG. 2G. The package 200 is flipped back over so that the front side 228 is up and the backside 226 is down. The package 200 may be heated (approximately 900°C) to anneal the conductive paste material 236 (see FIG. 2G), for example Ti/Ni (Ag-Sn Ink Squeegee) material, to make vias 240 through the ceramic interposer 214. The vias 240 may have wide band gap WBG quality factor – low noise and good heat transfer characteristics. The vias 240 may be described as through-silicon vias (TSV) and may have a height 208 of 100-600 µm and a width 210 of 50-500 µm.

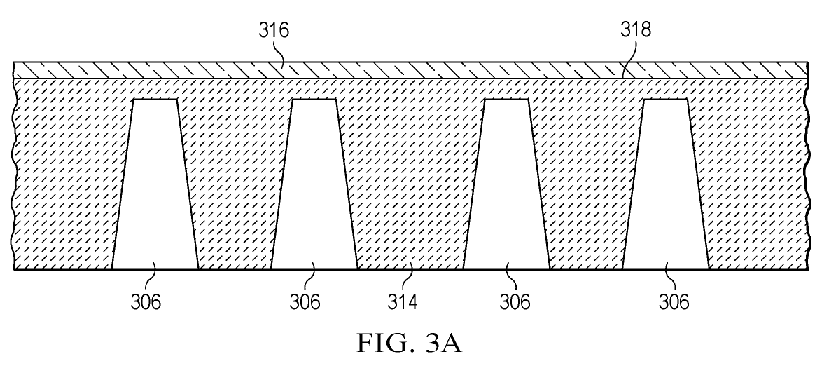

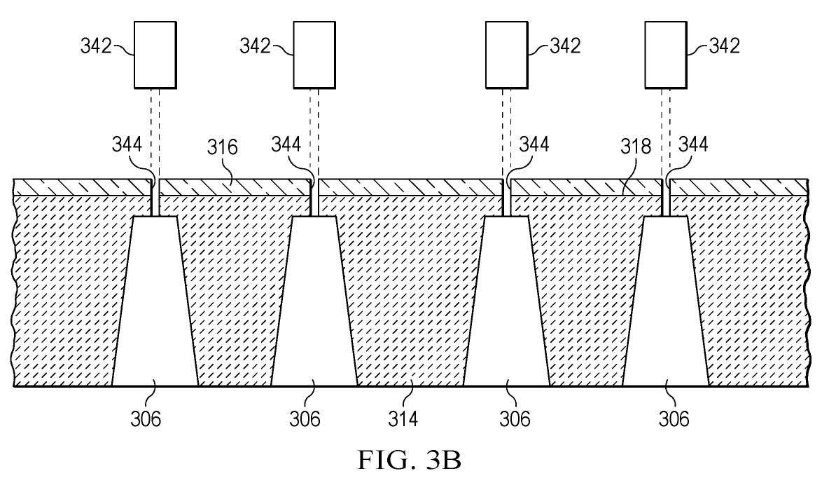

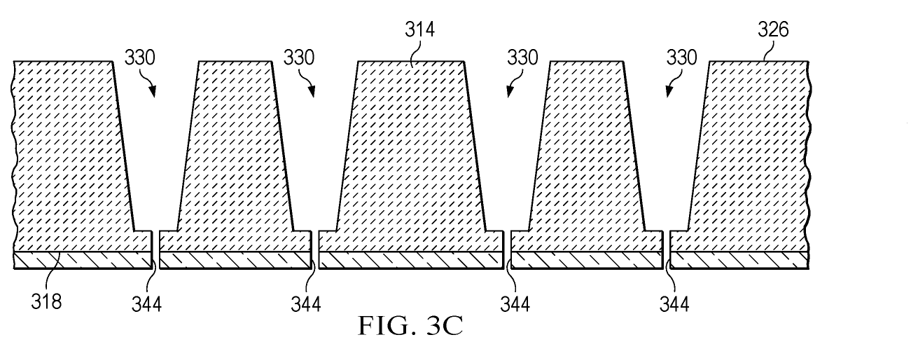

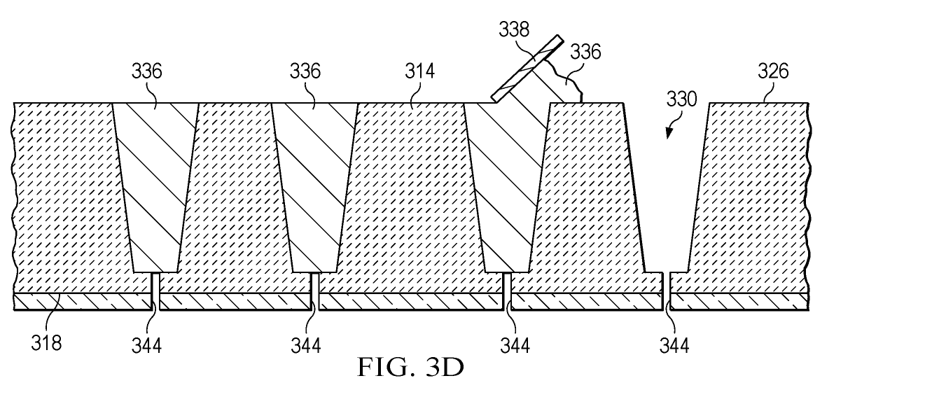

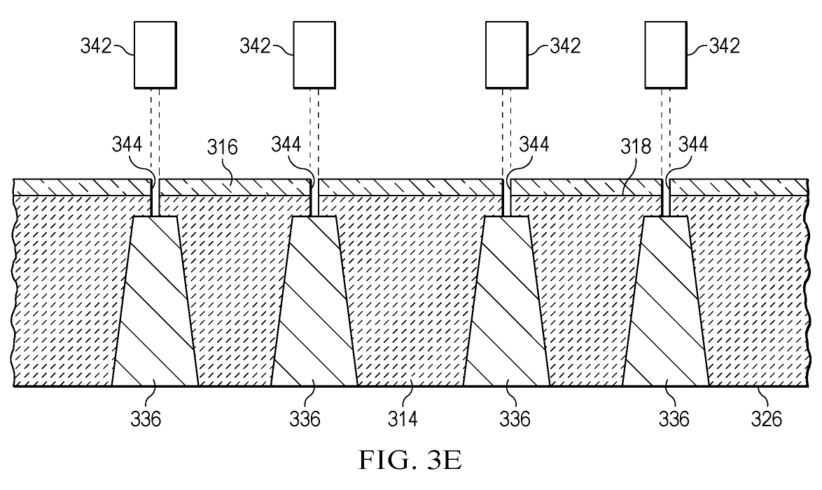

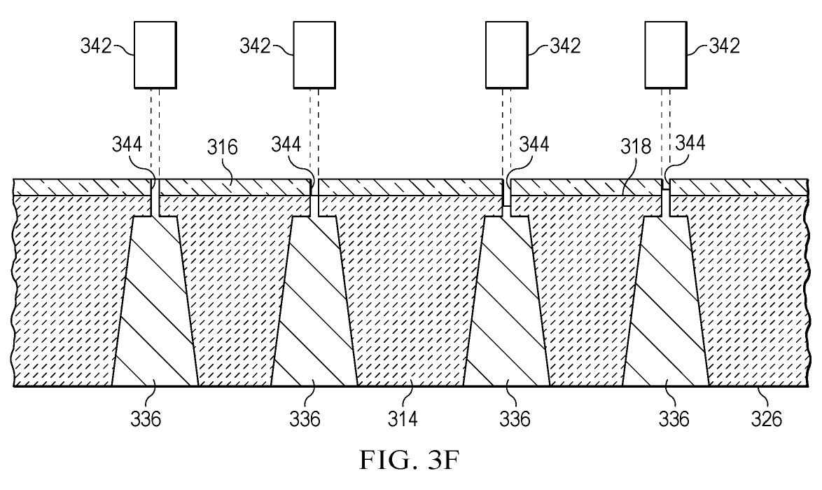

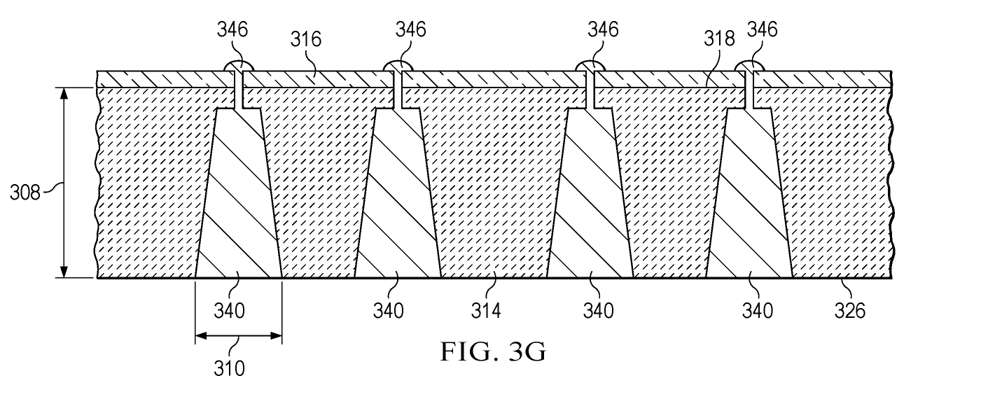

FIGS. 3A – 3G show fabrication of a ceramic interposer with through-silicon vias (TSV).

FIG. 3A shows a cross-sectional side view of a pressed poly-SiC (powder) ceramic interposer 314 having silicon mandrels 306 as shown in FIG. 1E. A diamondized spin on glass (SOG) layer 316 is applied to the front side 318 of the ceramic interposer 314 and annealed. The diamondized spin on glass (SOG) layer 316 may contain heat transfer enhancing particles, like diamond, AlN, or SiC.

FIG. 3B shows a cross-sectional side view of a pressed poly-SiC (powder) ceramic interposer 314 having silicon mandrels 306 as shown in FIG. 3A. Lasers 342 are used to cut small diameter holes 344 through the diamondized spin on glass (SOG) layer 316 and the amorphous polySiC ceramic material of the ceramic interposer 314 between the silicon mandrels 306 and the spin on glass (SOG) layer 316.

FIG. 3C shows a cross-sectional side view of a pressed poly-SiC (powder) ceramic interposer 314 as shown in FIG. 3B. The silicon interposer 314 is flipped up-side-down to expose the backside 326 of the silicon mandrels 306 (see FIG. 3B) in the ceramic interposer 314 to further processing. The silicon mandrels 306 have been removed from the ceramic interposer 314 by a potassium hydroxide (KOH) wash, to produce through openings 330 in the ceramic interposer 314, which connect with small diameter holes 344 that were cut by the lasers 342 (see FIG. 3B).

FIG. 3D shows a cross-sectional side view of the pressed poly-SiC (powder) ceramic interposer 314 as shown in FIG. 3C. A conductive paste material 336, for example Ti/Ni (Ag-Sn Ink Squeegee) material or copper based material, is then inserted into the through openings 330 via a squeegee 338 or other process. However, the conductive paste material 336 may be too viscus to flow through the small diameter holes 344.

FIG. 3E shows a cross-sectional side view of the ceramic interposer 314 as shown in FIG. 3D. The ceramic interposer 314 is flipped up-side-down to expose the front side 318 of the ceramic interposer 314 to further processing. The conductive paste material 336 may be locally heated by lasers 342 through the small diameter holes 344.

FIG. 3F shows a cross-sectional side view of the ceramic interposer 314 as shown in FIG. 3E. The lasers 342 locally heat the conductive paste material 336 until the conductive paste material 336 proximate the small diameter holes 344 liquifies and expands until it flows up through the small diameter holes 344.

FIG. 3G shows a cross-sectional side view of the ceramic interposer 314 as shown in FIG. 3F. The conductive paste material 336 (see FIG. 3F) has flowed up through the small diameter holes 344 to form ball pads 346 at the front side 318 of the ceramic interposer 314. The ceramic interposer 314 may be heated (approximately 900°C) to anneal the conductive paste material 336 (see FIG. 3F) to make vias 340 through the ceramic interposer 314. The vias 340 may have wide band gap WBG quality factor – low noise and good heat transfer characteristics. The vias 340 may be described as through-silicon vias (TSV) and may have a height 308 of 100-600 µm and a width 310 of 50-500 µm. Thus, the ceramic interposer 314 with vias 340 and ball pads 346 is fully formed.

In an alternative process, the small diameter holes are not pre-cut through the through the diamondized spin on glass (SOG) layer and amorphous polySiC ceramic material at the bottoms of the through openings in the interposer as shown in FIG. 3B, but rather the small diameter holes are cut simultaneously when the Ti/Ni (Ag-Sn Ink Squeegee) material is locally super-heated as shown in FIG. 3E. After a silver paste is squeegeed into the through openings, holes are laser drilled from the topside, which locally super heats up the silver and forces it through the small diameter laser-cut hole. It is similar to a volcanic eruption.

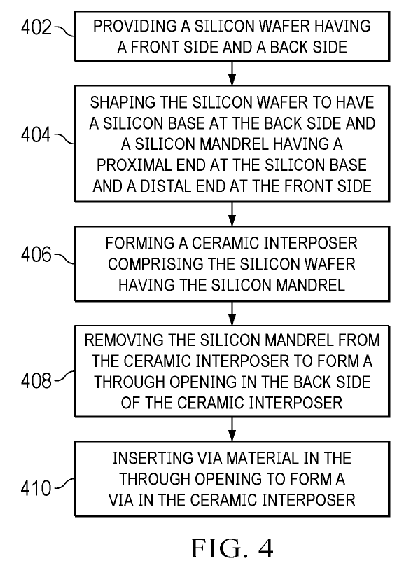

FIG. 4 shows a flow chart of a method creating a ceramic interposer with through-silicon vias (TSV). A silicon wafer having a front side and a back side is provided 402. The silicon wafer is shaped 404 to have a silicon base at the back side and a silicon mandrel having a proximal end at the silicon base and a distal end at the front side. A ceramic interposer is formed 406 comprising the silicon wafer having the silicon mandrel. The silicon mandrel is removed 408 from the ceramic interposer to form a through opening in the back side of the ceramic interposer. Via material is inserted 410 in the through opening to form a via in the ceramic interposer.

Although examples have been described above, other variations and examples may be made from this disclosure without departing from the spirit and scope of these disclosed examples.

What is claimed is:

1. A method comprising:
providing a silicon wafer having a front side and a back side;
shaping the silicon wafer to have a silicon base at the back side and a silicon mandrel having a proximal end at the silicon base and a distal end at the front side;
forming a ceramic interposer comprising the silicon wafer having the silicon mandrel;
removing the silicon mandrel from the ceramic interposer to form a through opening in the back side of the ceramic interposer; and
inserting via material in the through opening to form a via in the ceramic interposer.

2. The method as in claim 1, wherein shaping the silicon wafer comprises:
applying a photoresist pattern to the front side of the silicon wafer; and
etching the silicon wafer through the photoresist pattern to remove exposed portions of the silicon wafer and form the silicon mandrel.

3. The method as in claim 1, wherein forming a ceramic interposer comprises:
covering the front side of the silicon wafer having the silicon mandrel with a SiC powder; and
heating and pressing the SiC powder into an amorphous polySiC ceramic.

4. The method as in claim 1, wherein removing the silicon mandrel from the ceramic interposer comprises washing the back side of the ceramic interposer with a fluid to dissolve the silicon base and the silicon mandrel.

5. The method as in claim 1, wherein inserting via material comprises squeegeeing a conductive paste into the through opening.

6. The method as in claim 5, comprising heating the ceramic interposer to anneal the via material.

7. The method as in claim 1, comprising applying a spin on glass layer to the front side of the ceramic interposer.

8. The method as in claim 7, comprising etching the back side of the ceramic interposer through the through opening to remove a portion of the spin on glass layer.

9. The method as in claim 7, comprising:
cutting a hole through the spin on glass layer, so that the hole coincides with the through opening; and
heating the via material in the through opening to thermally expand the via material to flow into the hole through the spin on glass layer.

10. The method as in claim 1, comprising applying a semiconductor chip to the front side of the ceramic interposer.

11. The method as in claim 1, comprising encapsulating the front side of the ceramic interposer.

12. A device comprising:
an interposer having a front side and a back side, wherein the interposer comprises a SiC powder heated and pressed into an amorphous poly-SiC ceramic; and
a via extending from the front side to the back side of the interposer.

13. The device as in claim 12, wherein the via comprises titanium and nickel.

14. The device as in claim 12, wherein the via extends from 200 µm to 600 µm.

15. The device as in claim 12, comprising a spin on glass layer applied to the front side of the interposer, wherein the via extends through the spin on glass layer.

16. A system comprising:
an interposer having a front side and a back side, wherein the interposer comprises a SiC powder heated and pressed into an amorphous poly-SiC ceramic;
a via extending from the front side to the back side of the interposer; and
a semiconductor chip on the front side of the ceramic interposer and connected to the via.

17. The system as in claim 16, wherein the via extends from 200 µm to 600 µm and comprises titanium and nickel.

18. The system as in claim 16, comprising a spin on glass layer applied to the front side of the interposer between the semiconductor chip and the interposer, wherein the via extends through the spin on glass layer, wherein the spin on glass layer comprises particles having a relatively higher heat transfer coefficient than a material of the spin on glass layer.

19. The system as in claim 16, comprising an integrated passive device applied to the semiconductor chip.

20. The system as in claim 16, comprising an encapsulant encapsulating the semiconductor chip.
